(19) United States
(12) Patent Application Publication
(10) Pub. No.: US 2010/0180143 A1
(43) Pub. Date: Jul. 15, 2010

(54) TECHNIQUES FOR IMPROVED TIMING CONTROL OF MEMORY DEVICES

(75) Inventors: Frederick A. Ware, Los Altos Hills, CA (US); Carl Werner, Los Gatos, CA (US); Ian Shaeffer, Los Gatos, CA (US)

Correspondence Address: HUNTON & WILLIAMS LLP/RAMBUS INC.;INTELLECTUAL PROPERTY DEPARTMENT, 1900 K STREET, N.W., SUITE 1200, WASHINGTON, DC, 20006-1109, US

(73) Assignee: Rambus Inc., Los Altos, CA (US)

(21) Appl. No.: 12/596,360

(22) PCT Filed: Apr. 14, 2008
(86) PCT No.: PCT/US2008/060172

§ 371 Date: Mar. 2, 2010

Related U.S. Application Data
(60) Provisional application No. 60/912,743, filed on Apr. 19, 2007.

(51) Int. Cl. G06F 1/04; G11C 7/00; G06F 12/00

(52) U.S. Cl. 713/600; 365/193; 711/105; 711/E12.001

(57) ABSTRACT

Techniques for improved timing control of memory devices are disclosed. In one embodiment, the techniques may be realized as a memory controller to communicate with a memory device via a communications link. The memory controller may comprise a memory interface to exchange data with the memory device via a set of N conductors according to at least one clock, the data being encoded such that each M bits of data are represented by at least one symbol and each symbol is associated with a combination of signal levels on a group of n conductors, wherein M<N and n is equal to at least one and at most N. The memory may also comprise clock control logic to receive timing calibration information from the memory device and to output a signal to adjust a phase of the at least one clock based on the timing calibration information.

### CROSS-REFERENCE TO RELATED APPLICATIONS

This patent application claims priority to U.S. Provisional Patent Application No. 60/912,743, filed Apr. 19, 2007, which is hereby incorporated by reference herein in its entirety.

This patent application is a national phase application of International Patent Application No. PCT/US2008/060172, filed Apr. 14, 2008, which is hereby incorporated by reference herein in its entirety.

### FIELD OF THE DISCLOSURE

The present disclosure relates generally to electronic devices and data communications therewith, and, more particularly, to techniques for improved timing control of memory devices.

### BACKGROUND OF THE DISCLOSURE

Standard double data rate (DDR) and graphics double data rate (GDDR) memory devices typically operate based on a strobed timing architecture which is one type of “source synchronous timing.” For example, a memory controller (e.g., a graphics processing unit or “GPU”) may be coupled to a DDR or GDDR memory device via a bi-directional data bus, and a pair of strobe paths may run in parallel with the data bus to provide timing control for high-speed data exchange between the memory controller and the memory device. In operation, the memory controller may assert a first strobe signal (or “write strobe”) on one strobe path to provide a timing reference for every transmission of data to the memory device. The memory device may assert a second strobe signal (or “read strobe”) on the other strobe path to provide a timing reference for every transmission of data to the memory controller. With this timing arrangement, the receiving device (i.e., the memory controller during a read operation or the memory device during a write operation) can have a timing reference which is in a controlled phase relationship with the data signal received.

Some higher-performance memory devices operate based on a clocked timing architecture and include timing circuitry to generate an internal clock based on a master clock supplied by a memory controller. Write data signals are not sampled according to the timing of write strobe signals but in reference to an internal receive clock signal at the memory. Similarly, read data signals are not sampled according to the timing of read strobe signals but in reference to a receive clock signal at the memory controller. With such a clocked timing architecture, there is no need to equalize the electrical lengths of timing and data paths to avoid skew between strobe and data signals. Therefore, the complexity of laying out the memory controller, the memory device and the circuit board can be significantly lessoned. The clocked timing architecture, however, requires proper phase maintenance for the transmit and receive clocks to sample data signals at the memory and the memory controller. Such requirement may be difficult to satisfy when environmental drift components are present in the memory device to cause continual phase drift in its local clock.

In view of the foregoing, it would be desirable to provide a technique for improved timing control of memory devices which overcomes the above-described inadequacies and shortcomings.

### BRIEF DESCRIPTION OF THE DRAWINGS

In order to facilitate a fuller understanding of the present disclosure, reference is now made to the accompanying drawings, in which like elements are referenced with like numerals. These drawings should not be construed as limiting the present disclosure, but are intended to be exemplary only.

FIG. 1 shows a block diagram illustrating an exemplary system for improved timing control of memory devices in accordance with an embodiment of the present disclosure.

FIG. 2 shows an exemplary memory system including a memory controller communicating with a clock-based DRAM device in accordance with an embodiment of the present disclosure.

FIG. 3 shows a block diagram illustrating an exemplary circuit for encoding, transmitting, receiving and decoding data signals associated with six data wires in accordance with an embodiment of the present disclosure.

FIG. 4 shows an exemplary encoding table for encoding symbols on six data wires in accordance with an embodiment of the present disclosure.

FIGS. 5A and 5B show a comparison of signal quality between a multi-wire encoded transmission and a single-ended data transmission.

FIG. 6 illustrates write phase calibration in a memory system having a memory controller operating in a clock mode in accordance with an embodiment of the present disclosure

FIG. 7 illustrates write phase calibration by a memory controller operating in a clock mode in accordance with an alternative embodiment of the present disclosure.

FIG. 8 illustrates read phase calibration by a memory controller operating in a clock mode in accordance with an embodiment of the present disclosure.

FIG. 9 shows a block diagram illustrating an exemplary memory controller in accordance with an embodiment of the present disclosure.

FIG. 10 shows a block diagram illustrating an exemplary clock-based memory device in accordance with an embodiment of the present disclosure.

FIG. 11 shows an exemplary bimodal memory controller operating in a strobe mode with a strobe-timed DRAM device in accordance with an embodiment of the present disclosure.

### DETAILED DESCRIPTION OF EXEMPLARY EMBODIMENTS

Embodiments of the present disclosure provide techniques for improved timing control of memory devices. A memory controller may coordinate with a clock-based memory device to calibrate phase offsets associated with transmit and/or receive clocks, and phase calibration information may be conveyed on the same wires that carry data between the memory controller and the memory device. The phase calibration information may be encoded and transmitted on one or more of the data wires according to a multi-wire encoding scheme. In addition, a bimodal controller may be provided to interoperate with either strobe-timed memory devices or clock-based memory devices.

Although the description that follows will focus on communications between a memory controller and a memory device (e.g., a GPU and a GDDR memory), the techniques are not limited to memory controllers and memory devices, but may be generally applicable to high-speed data communications between two or more integrated circuit (IC) components (e.g., between a master device and one or more slave devices).

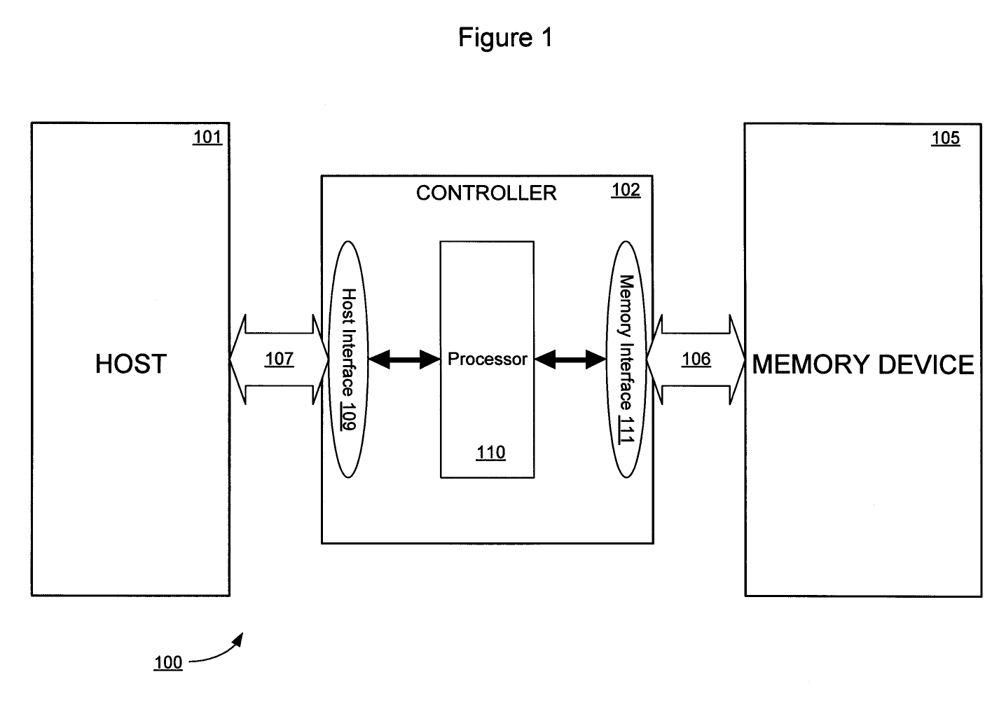

FIG. 1 shows a block diagram illustrating an exemplary system 100 comprising a host 101, a controller 102, and a memory device 105. The controller 102 may comprise a processor 110, a host interface 109, and a memory interface 111. The host interface 109 enables communications between the host 101 and the controller 102 via a first communications link 107, and the memory interface ill enables communications between the controller 102 and the memory device 105 via a second communications link 106. The host 101 may send input/output (I/O) requests to the controller 102, and the controller 102 may process the I/O requests and execute them against the memory device 105. The controller 102 may detect the type and/or operating mode (i.e., strobe mode versus clock mode) of the memory device 105 and adapt its communications with the memory device 105 accordingly. Specifically, the memory interface 111 and/or the second communications link 106 may be configured to support either a strobe mode or a clock mode.

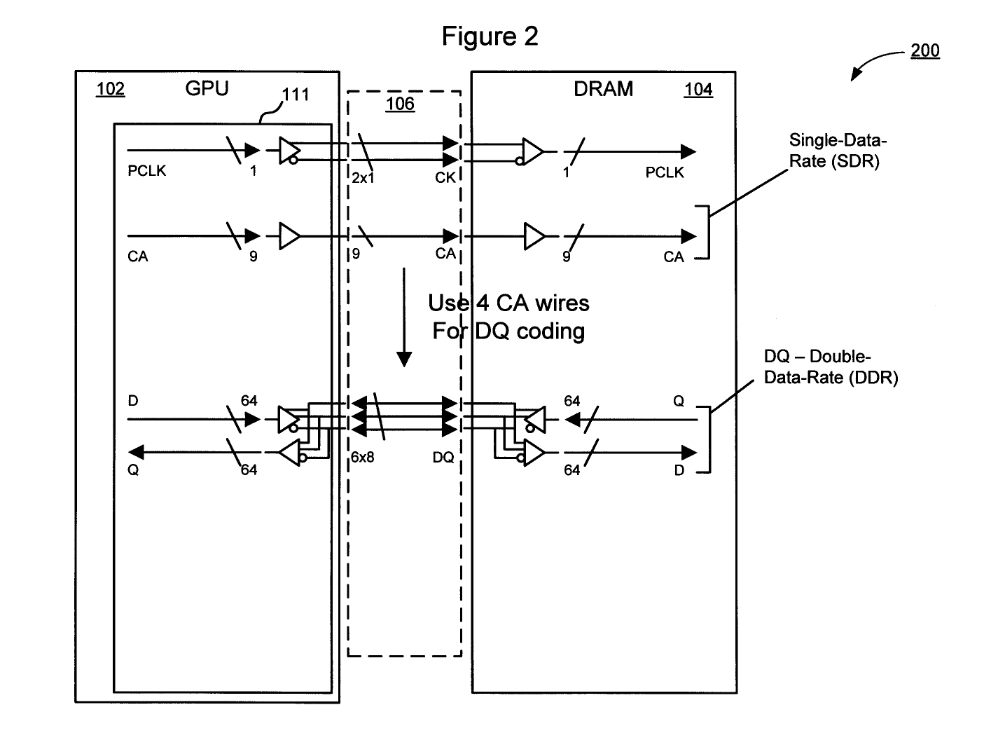

FIG. 2 shows an exemplary memory system 200 including a memory controller 102 communicating with a clock-based memory device, such as a DRAM device 104, in accordance with an embodiment of the present disclosure. The memory controller 102 may be a GPU, and the DRAM 104 may be a GDDR memory device that operates based on internally or externally generated clock signals. The GPU 102 may comprise a memory interface 111 that is coupled to the DRAM 104 via a communications link 106 including a first set of wires forming a clock path for conveying clock signals (CK), a second set of wires forming a CA path for conveying command and/or address signals (CA), and a third set of wires forming a data path for conveying data signals (DQ). The CA path may be a 9-bit wide, uni-directional single-data-rate (SDR) signaling path. A PCLK signal may be provided to the DRAM 104 as a clock source through the clock path.

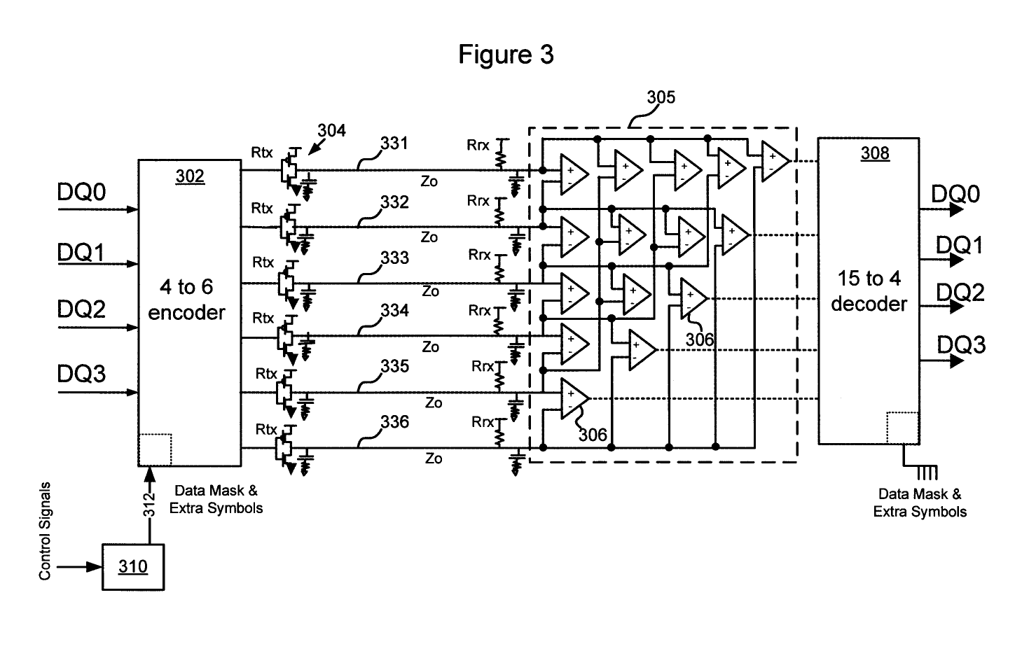

According to one embodiment, as shown in FIG. 2, the third set of wires may include N DQ wires employed to convey in parallel M bits of encoded DQ data at an enhanced signal quality, wherein N>M. For example, 48 wires may be used to convey 32 bits of data in parallel. The 48 wires may be grouped in groups of 6 wires so that every 6 data wires (DQ) may be used to convey 4 bits of encoded data in one bit interval, according to a multi-wire encoding scheme. Or, the wires may be grouped in groups of 3 data wires so that every 3 data wires may be used to convey 2 bits of encoded data in one bit interval, according to another multi-wire encoding scheme. Thus, when transmitted in double data rate, every 6 wires may be used to convey 1 byte (8 bits) of data in one clock cycle, and the 48 wires may be used to convey 8 bytes of data in one clock cycle. According to a multi-wire encoding scheme, multiple conductors may be coupled between a transmission source and a transmission destination. Multiple drivers may be coupled to the conductors at the transmission source, each driver being coupled to an end of a conductor. Multiple comparators may be coupled to the conductors at the transmission destination, each comparator being coupled to a pair of conductors. Information to be transmitted may be encoded into symbols in which each symbol represents a unique combination of signal levels on a group of conductors. In one embodiment, there are two different signal levels for each wire. In another embodiment, where multilevel signaling is used, there may be three or more different signal levels for each wire. In one embodiment, each signal level is used at least once for each symbol, and all signal levels in the combination of signal levels associated with a particular symbol are transmitted over respective conductors in parallel. More detail of an exemplary multi-wire encoding scheme will be provided below in connection with FIGS. 3-5.

FIG. 3 shows a block diagram illustrating an exemplary circuit 300 for encoding, transmitting, receiving and decoding data signals associated with six data wires in accordance with an embodiment of the present disclosure. The circuit has a transmitter side including a 4-to-6 encoder 302 and a plurality of invertors 304. That transmitter side may be part or all of a transmit circuit in the controller 102 or the memory 104. Four bits of DQ data (i.e., DQ0-DQ3) may be fed into the 4-to-6 encoder 302 having six outputs, each of which may be coupled to one of six data wires 331-336 through an inverter 304. The encoder outputs depend on the data inputs DQ0-DQ3 and may also depend on one or more control signals 312 from a control circuit 310, which responds to one or more control inputs. The function of the control circuit 310 is discussed further below. The data wires 331-336 may be coupled to a receiver having a network 305 of 15 comparators 306 each having its output coupled to a 15-to-4 decoder 308. The receiver may be part or all of a receive circuit in the controller 102 or the memory 104 as shown in FIG. 2. Each comparator 306 may include a two-level pulse amplitude modulation (2-PAM), full differential amplifier. The arrangement of the data wires 331-336 and the 15 comparators 306, according to a multi-wire encoding scheme, may cause a total output current on the six data wires 331-336 to be at a substantially constant level, thereby avoiding ground bounces caused by current swings.

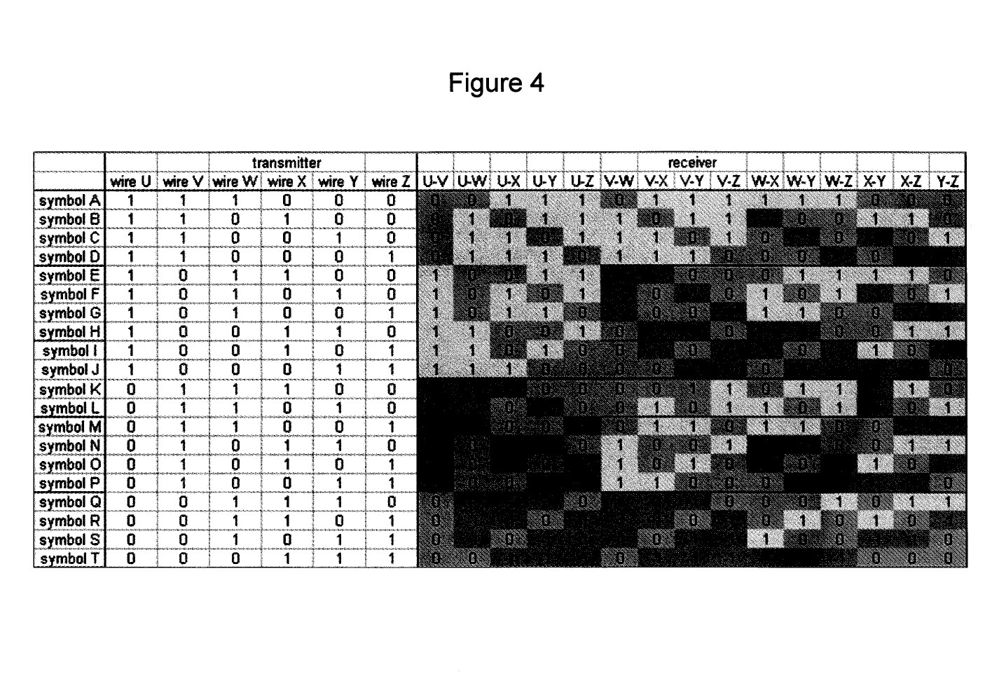

In one embodiment, the encoding of the data into symbols results in constant total output current on the six data wires. This is illustrated in FIG. 4, which shows an exemplary encoding table for a list of symbols for transmitting on the six data wires 331-336 at the transmitter side in FIG. 3 and their corresponding comparator outputs at the receiver side in FIG. 3 in accordance with an embodiment of the present disclosure. On the transmitter side of FIG. 3 (i.e., at the output of inverters 304), the six data wires 331-336 may be denoted wires U, V, W, X, Y, and Z, respectively, as shown in FIG. 4. Assuming each wire has 2 different levels of current values to select from and with the constraint that the sum of the current values of all six wires be constant, a total of 20 different symbols (i.e., symbols A through T) may be defined. 16 symbols (e.g., the first 16 of the 20 symbols, symbols A through P) may be used to represent respective ones of the possible combinations of the digital values at the 4-bit input DQ0-DQ3.

The remaining four symbols (e.g., symbols Q through T) may be used for a number of functions other than representing the input data. For example, one or more extra symbol may be employed as one or more data mask (DM) symbols for data masking. In conventional memory systems, a data mask (DM) signal is sometimes used to accompany write data to indicate that certain write data is not to be written into memory. In one embodiment, there is no need to send a separate DM signal as a data mask. Instead, one or more DM symbols are sent over the data wires to serve as data mask. For instance, in the encoding table shown in FIG. 4, symbol Q may be used as a DM symbol. So, for each 4 bits of data to be masked, as shown in FIG. 3, a DM control input signal is received by a control circuit 310 in the controller 102. The control circuit 310 sends a control signal 312 to the encoder 302 to the 4 bits of data to be masked into symbol Q. In other words, one symbol Q can be sent to the memory as a substitute for the symbol representing the 4 bits of data to be masked. The decoder 308 (FIG. 3) in the memory 104 can be configured to recognize symbol Q as a data mask and not output data for writing into memory.

The extra symbols may also be used to transmit calibration information, such as clock phase adjustment information. For instance, symbol A may be used to encode a certain read data value, such as the value “0000,” and symbol R and S may coordinate with symbol A to perform a calibration function. For example, when the memory sensed that the phase of a transmit clock in the controller should be incremented, the control circuit 310 (FIG. 3) in the memory 104 receives the information at its control input and send a control signal 312 (FIG. 3) to instruct the encoder 302 to encode the data to be represented by symbol A into symbol R. The decoder 308 (FIG. 3) in controller 102 may include a control circuit (not shown) that is configured to recognize symbol R among symbols representing read data, and output a control signal (not shown) to increment the phase of the transmit clock. Also, the decoder 308 would treat symbol R as symbol A by, for example, replacing symbol R with symbol A or decoding symbol R into the data value represented by symbol A. Similarly, when the memory sensed that the phase of the transmit clock in the controller should be decremented, it sends symbol S in place of symbol A to indicate that the transmit clock phase is to be decremented. The controller, receiving symbol S among other symbols, would treat symbol S as symbol A and would act to decrement the phase of the transmit clock. This would permit the transmit phase to be updated whenever the read data represented by symbol A (e.g., “0000”) is returned, which is about 1/16 of the time on average.

A third function that may be served by the extra symbols is that of an embedded error code channel. For example, the R and S symbols could both be used to encode the data value “0000”, with one indicating an odd parity and the other indicating an even parity. The parity value may be accumulated between occurrences of the data value “0000.”

A fourth function served by the extra symbols may be that of error detection feedback from the DRAM 104 to the controller 102. For example, the symbol T may be used to replace symbol A to indicate a read data value of “0000,” and to indicate that the DRAM 104 detected an error in a previous burst of write data. An alternate error detection scheme may include parity information transmitted alongside or interspersed with data.

On the receiver side of FIG. 3, the outputs of the 15 comparators 306 may provide comparison results for 15 possible pairs of wires among the 6 wires U through Z. In one embodiment, as shown in FIG. 4, each wire has a signal level of either zero or one, and the comparison result between any two wires may be −1, 0, +1. A zero condition indicates “don't care.” Since differential receivers are most sensitive to noise when the inputs are in the zero condition, and since variance in the random offset voltage across all receivers make the behavior unsystematic, the receivers cannot be trusted to reliably detect the zero condition. As such, the coding in FIG. 4 is chosen to ensure that the decoder 308 will correctly resolve the data symbols regardless of unreliable detection of the zero condition. This encoding method allows the use of simple, economic receiver circuits. As shown in FIG. 4, without using the “0” or the “−1” outputs, each 15-bit row on the receiver side of the encoding table still uniquely corresponds to one of symbols A through T on the transmitter side. Therefore, the 15-to-4 decoder 308 can reliably decode the outputs of the comparators 306.

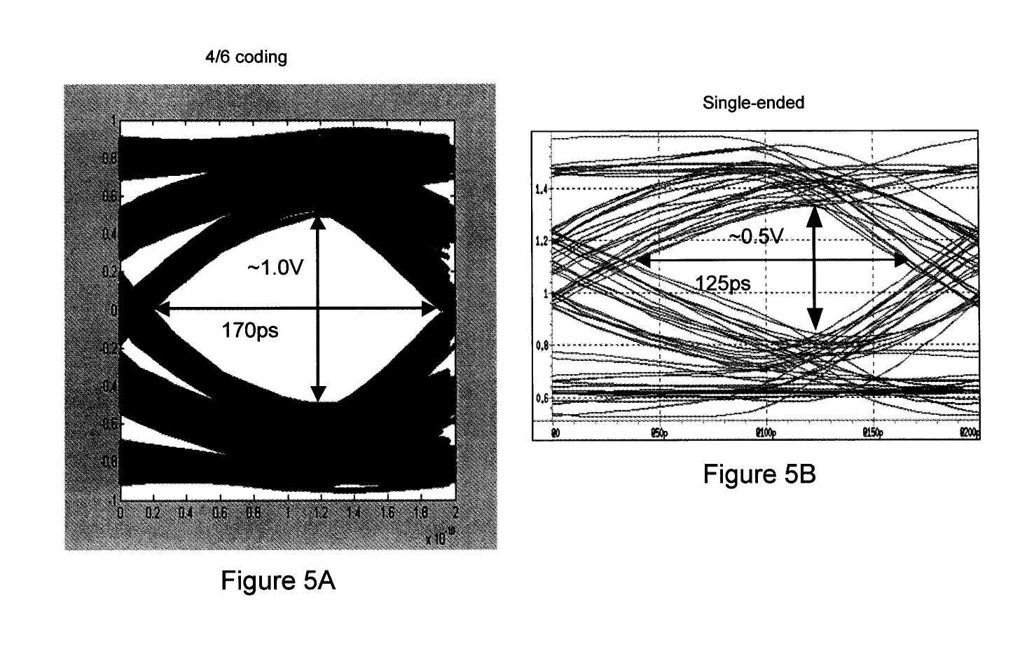

According to embodiments of the present disclosure, this multi-wire encoded transmission of DQ data can significantly enhance data rate and signal quality of the DQ data. FIGS. 5A and 5B show a comparison of signal quality between a multi-wire encoded transmission and a single-ended data transmission. With the multi-wire encoded transmission of FIG. 5A, the DQ data signals have smaller crosstalk (due to a smaller number of nearby switching bits for each data wire), more opening in the “data eye,” and smaller jitter than the single-ended data transmission of FIG. 5B.

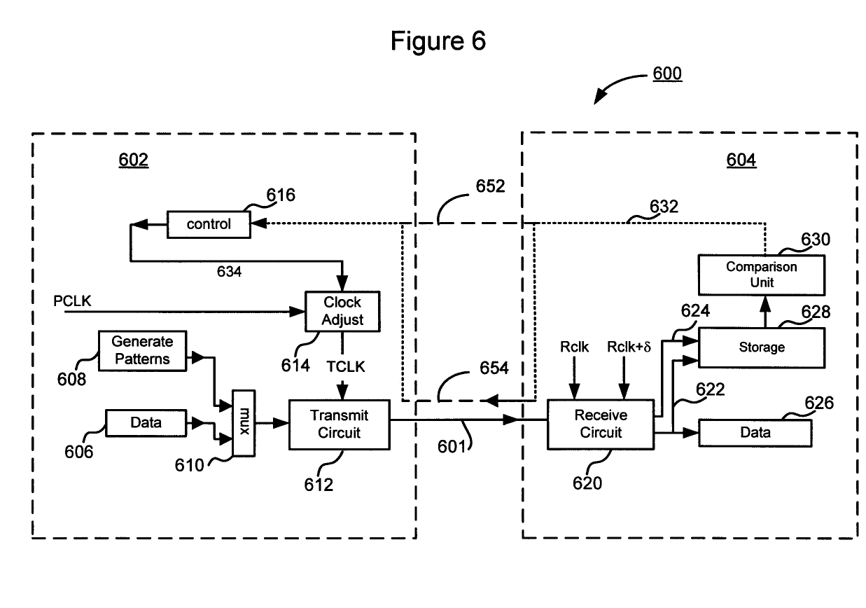

When operating in a clock mode (i.e., reading and writing data with clock signals, instead of strobe signals, as a timing reference), it is desirable that a memory controller coordinates with a corresponding clock-based memory device to properly calibrate or maintain read and write phase offsets between data and clocks. The clock signals for timing the transmission and/or reception of write and/or read data in the controller can be derived from an internal or external clock signal, such as the PCLK signal, using, for example, phase adjustment circuits. In one embodiment, the DQ wires are divided into groups such that the clock signals for different groups of DQ wires can have phases independent from each other, at least at the controller side. The number of wires in each group can range between 1 to the total number of wires. For example, 48 DQ wires may be divided into 8 groups of 6 DQ wires and a phase adjustment circuit is associated with each group of 6 DQ wires. In other embodiments, the clock signal for each DQ wire can be independently adjusted. Calibration or maintenance of the phase offsets between data and clock for each group of DQ wires may be achieved with closed-loop calibration paths. For example, during a write operation, the memory device may derive phase calibration or maintenance information based on received write data signals. The phase calibration or maintenance information may be transmitted to the memory controller after the write operation during, for example, a read operation, via a dedicated or shared signal link. In one embodiment, there may be a separate closed-loop calibration path for each group of DQ wires. In a further embodiment, a closed-loop calibration path associated with one group of DQ wires can be used to maintain phase offsets for several groups of DQ wires. In another embodiment, phase calibration or maintenance information is derived separately for each group of DQ wires and an averaging or voting scheme is used to derive averaged/selected phase calibration or maintenance information from the phase calibration or maintenance information for the several groups of DQ wires. The averaged/selected phase calibration or maintenance information can be transmitted back to the memory controller via a dedicated or shared link, and is used by the memory controller to calibrate or maintain the phase offsets for the several groups of DQ wires. This way, only one dedicated or shared link is needed to transmit a phase calibration or maintenance signal for several groups of DQ wires. Further examples of phase offsets calibration or maintenance are illustrated in FIGS. 6-8.

FIG. 6 illustrates write phase calibration in a memory system 600 having a memory controller 602 and a memory device 604 (e.g., a DRAM) operating in a clock mode in accordance with an embodiment of the present disclosure. The memory controller may select either write data 606 or a data pattern 608 via a multiplexer 610 for transmission to memory 604. The data pattern is sometimes selected instead of data to ensure that there is sufficient transition density in the transmitted signal for calibration. The controller 602 includes a transmit circuit 612 to transmit the selected data or data pattern over a group of wires 601. The transmit circuit 612 is driven by at least one transmit clock TCLK, which may be derived from PCLK using a clock adjusting circuit 614. In one embodiment, the transmit circuit 612 include an encoder, such as the encoder 302 in FIG. 3. A multi-wire encoding scheme, such as the ones described above, may be implemented to encode the data 606 or data pattern 608 into symbols to transmit over the group of wires 601. Although, for ease of illustration, only one line is shown as the group of wires 601, the group of wires may include 1 to N data wires, where N is the total number of data wires between controller 602 and memory 604. In one embodiment, the encoding scheme shown in FIGS. 3 and 4 can be used. So the group of wires 601 may include 6 wires to convey in parallel one of the symbols A through T.

The transmit clock (TCLK) in the controller 602 may provide timing control for data transmission from the controller 602 to the memory 604. In the memory 604, a receive circuit 620 receives the symbols transmitted over the group of wires 601. One or more receive clocks (e.g., Rclk and Rclk+δ), which can be derived from PCLK or from a clock source in the memory 604, may provide timing control for data reception in the memory 604. In one embodiment, the receive circuit 620 may include two sets of circuits (not shown), a first set of circuits and a second set of circuits. Each set of circuits may have a set of comparators, such as the comparators 306, and a 15 to 4 decoder, such as the 15 to 4 decoder 308. The first set of circuits sample input symbols according to Rclk, while the second set of circuits sample input symbols according to Rclk+δ, which has a predetermined or fixed phase offset δ from Rclk. The fixed phase offset δ can be, for example, about a quarter of a clock cycle. So, receive circuit 620 may generate two sets of data 622 and 624 from the first and second sets of circuits, respectively. Data 622 may be written into memory as write data 626. In one embodiment, the memory 604 further includes a comparison unit 630, which may include a logic circuit to derive phase calibration information from the outputs of the receive circuit 620. For example, data 622 may be compared with respective bits of data 624 by the comparison unit 630. The result of the comparison may be stored in a storage unit 628, which may be a register or a buffer in a memory interface or a portion of a memory core in the memory 604. Or, as shown in FIG. 6, the data 622 and 624 may be stored in the storage 628 for later processing by the comparison unit 630.

The comparison unit 630 outputs a comparison result 632 as phase calibration or maintenance information, which may indicate whether the phase of TCLK should be incremented or decremented based on the comparison. The comparison result 632 may be transmitted to the memory control 602 during, for example, a memory read operation. The comparison result 632 may be transmitted as one or more phase calibration signals over one or more dedicated signal lines 652, or over one or more shared signal lines 654, which may be the group of wires 601. In one embodiment, two phase calibration signals may be transmitted—one to indicate that the phase of TCLK should be incremented and another to indicate that the phase of TCLK should be decremented.

In other embodiments, a shared link is used to transmit the comparison result and the comparison result 632 is transmitted using a transmit circuit (such as the one shown in FIG. 3) in memory 604 over the group of wires 601 in the form of one or more symbols. In one embodiment, as described above, the comparison result 632 is transmitted in the form of one or more of the extra symbols not used for data transmission. For example, as discussed above, when the comparison result 630 indicates that the phase of the transmit clock (TCLK) in the controller 602 should be incremented, the transmit circuit in the memory 604 can be configured to find an opportunity when a particular symbol, such as symbol A, is to be transmitted as part of read data and replaces symbol A with symbol R. Similarly, when the comparison result 632 indicates that the transmit clock in the controller 602 should be decremented, the transmit circuit in memory 604 sends symbol S in place of symbol A. In one embodiment, the controller 602 includes a control circuit 616 to detect the presence of R and S symbols in the incoming symbols and to send a control signal 634 to instruct the clock adjust circuit 614 to increment or decrement the phase of TCLK accordingly. The control signal 634 may be filtered to remove high-frequency changes in the phase. The controller 602 would also treat each occurrence of symbol R or S as representing the data represented by symbol A and decode symbol R or S accordingly. Thus, the phase adjustment information can be sent with the read data without interruption of the data flow.

For a write operation in the clock mode, it is desirable that Rclk in the memory 604 have an appropriate phase offset with respect to TCLK in the controller 602, or vice versa. The appropriate phase offset may be referred to as a “write phase offset” as it may be adjusted on the transmitting end by adjusting the phase of TCLK. As described above, to determine the write phase offset, a block of data or a data pattern may be encoded into symbols and clocked by TCLK onto data wires 601 during, for example, a write operation. The symbols representing the data or data pattern are received in the DRAM 604 and clocked in with clock signals Rclk and Rclk+δ, which have a fixed phase offset between each other. This results in two sets of data being output by receive circuit 620 for each received symbol. The comparison unit 630 may then perform a bit-wise comparison between the two sets of data or data patterns. The comparison result and any other phase calibration information may then be transmitted back to the controller 602, via the same wires 601. The comparison result may indicate whether the phase of TCLK should be incremented or decremented. The comparison result and any other phase calibration information may be forwarded to a control unit 616 in the controller 602, which in turn causes the TCLK phase to be incremented or decremented. As a result, a closed feedback loop for write phase maintenance may be formed and the write phase offset may be efficiently calibrated or maintained. In some embodiments, the control unit 616 may use the comparison result received via one group of wires and use the result to adjust the phases of the TCLK's for the same group of wires and for other groups of wires. This way, the other groups of wires gain the extra bandwidth by not having to use the same extra symbols for phase calibration and can use the extra symbols for other purposes.

According to another embodiment, it may be advantageous to perform write phase calibration during core refresh of the DRAM 604. A refresh command, which directs the memory core in the DRAM 604 to perform a refresh operation, may direct the memory interface of controller 602 to transmit a data pattern to the DRAM 604. The data pattern may be received by the DRAM 604 according to clock signals Rclk and Rclk+δ and then compared. The comparison result may be sent back to the control unit 616 either immediately or at a later time not during the refresh operation.

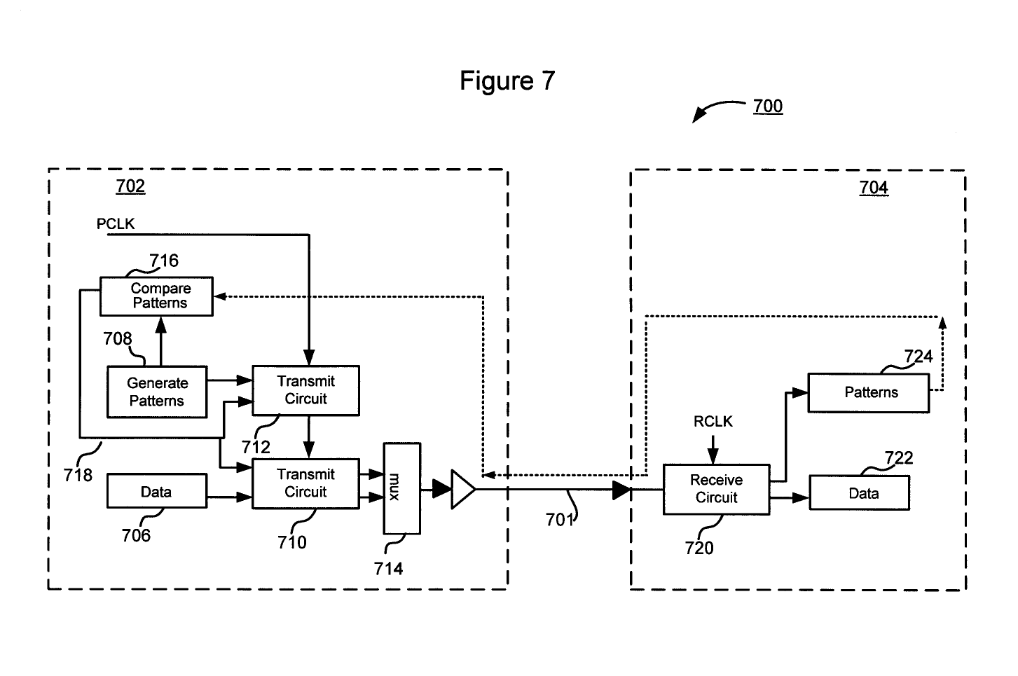

FIG. 7 illustrates write phase calibration by a memory controller 702 operating in a clock mode in accordance with an alternative embodiment of the present disclosure. The memory controller 702 may comprise a first transmit circuit 710 for encoding and transmitting data 706, a second transmit circuit 712 for encoding and transmitting a data pattern 708, and a multiplexer 710. The first transmit circuit 710 receives PCLK and includes a phase adjust circuit (not shown) to generate a transmit clock TCLK from PCLK. The second transmit circuit 712 also receives PCLK and includes a phase adjust circuit (not shown) to generate a transmit clock TCLK+Δ from PCLK. TCLK and TCLK+Δ have a predetermined or fixed phase offset from each other. TCLK times the transmission of data 706, and TCLK+Δ times the transmission of the data pattern 708. Multiplexer 710 selects either the encoded data or the encoded data pattern for transmission over a group of wires 701, which may include one to N data wires, wherein N is the total number of data wires between controller 702 and 704.

The DRAM 704 may comprise a receive circuit 720 to receive and decode the encoded data or data pattern. The decoded data 722 may be written into memory, while the decoded data pattern may be stored in a data storage component 724, which may be either a register or a buffer in a memory interface or a portion of a memory core in the DRAM 704. A receive clock (Rclk), which may be derived from PCLK or a clock signal in DRAM 704 provides timing control for the data reception.

A number of options exist for the implementation of write phase maintenance in the exemplary system illustrated in FIG. 7. Compared with the implementation illustrated in FIG. 6, in FIG. 7 a fixed phase offset may be imposed between TCLK and TCLK+Δ instead of between Rclk and Rclk+δ. Data patterns 708 may be encoded and clocked onto data wires 701 with clock signal TCLK+Δ. The encoded data patterns received in the DRAM 704 may be clocked in with clock signal Rclk. The received data patterns may then be compared with stored data patterns either at the DRAM 704 or at the controller 702.

According to one embodiment, the received data patterns are encoded into symbols and transmitted back to the controller 702 via the same set of wires 701, during, for example, a read operation. The controller 602, after receiving and decoding the data pattern, compares the data pattern with stored data patterns with a comparison unit 716. Alternatively, the comparison may take place in the DRAM 704, in which case the comparison result and/or other phase calibration information may be returned to the controller 702. In either case, a signal 718 may be generated to instruct the first and second transmit circuit 710 and 712 to either increment or decrement the phase of Tclk and TCLK+Δ, respectively. The signal 718 may be filtered to remove high-frequency changes in the phases. The transmission of the data patterns in either direction may be timed to occur during a core refresh of the DRAM 704. In addition, the comparison result, other phase calibration information, and/or the data patterns returned via the data wires 701 may be encoded using the extra symbols, as discussed above.

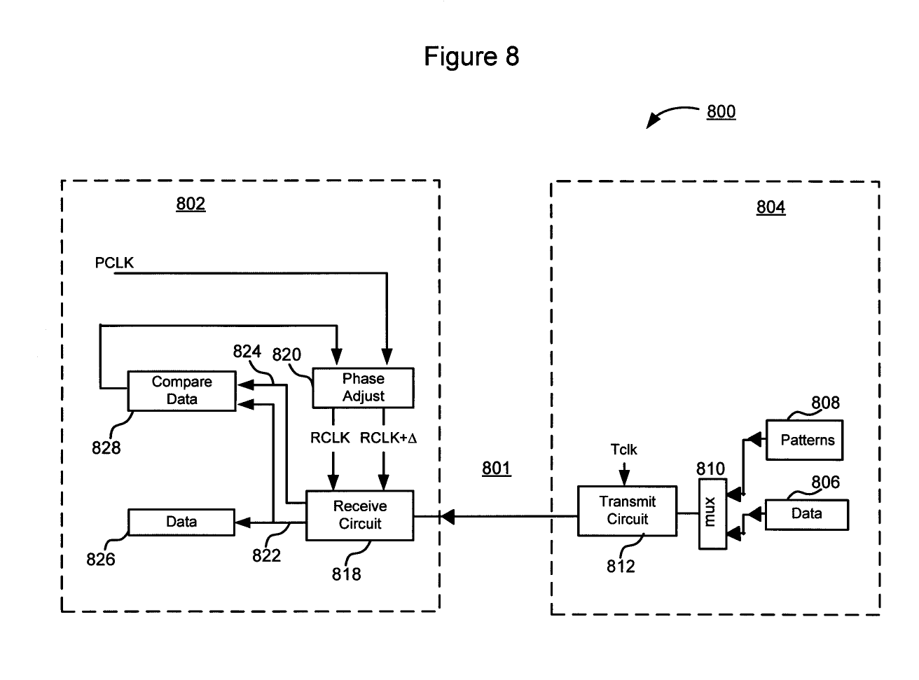

FIG. 8 illustrates an exemplary method for read phase maintenance by a memory controller 802 operating in a clock mode in accordance with an embodiment of the present disclosure. The controller 802 may be coupled to a clock-based DRAM 804 via a communications link including a group of data wires 801. The DRAM 804 may comprise a multiplexer 810 to select either data 806 or a data pattern 808 for transmission, and a transmit circuit 812 to encode the selected data or data pattern into symbols and transmit the symbols over the wires 801. A transmit clock (Tclk), which may be derived from PCLK or another clock in the DRAM 804, may provide timing control for data transmission from the DRAM 804 to the controller 802, such as in a read operation. On the receiving end, the controller 802 may comprise a receive circuit 818 to receive and decode the encoded data or data pattern. The receive circuit may include two sets of circuits (not shown) including a first set of circuits to receive the symbols according to a first receive clock RCLK and a second set of circuits to receive the symbols according to a second receive clock RCLK+Δ, which has a predetermined or fixed phase offset from RCLK. Both RCLK and RCLK+Δ may be derived from PCLK using one or more clock adjusting circuit 820. Thus, two sets of received and decoded data or data pattern are output from the two sets of circuits in the receive circuit 820, respectively.

Thus, in the clock mode, a read phase calibration may be started by transmitting data or data patterns from the DRAM 804 to the controller 802 under the timing control of Tclk. The data or data patterns received at the controller 802 may be clocked in with clock signals RCLK and RCLK++Δ. The controller 802 may further include a data register (or buffer) 826 and a comparison unit 828. The two sets data or data patterns may then be compared in the comparison unit 828 which outputs a signal to either increment or decrement the phase of RCLK. If the two sampled values are the same, then the RCLK phase may be adjusted such that it becomes harder for the second set of circuits clocked by the clock signal RCLK+Δ to output the same data value as the first set of circuits clocked by the clock signal RCLK. If the two sampled values are different, then the RCLK phase may be adjusted such that it becomes easier for the second set of circuits clocked by the clock signal RCLK+Δ to output the same data values as the first set of circuits clocked by the clock signal RCLK.

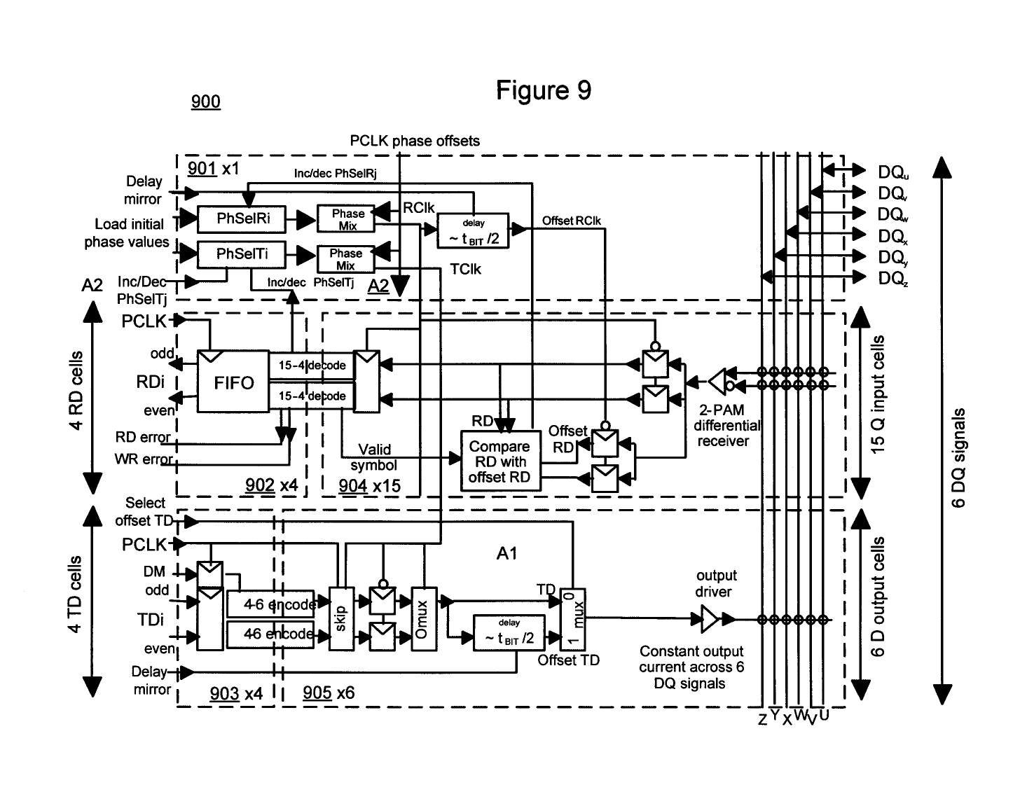

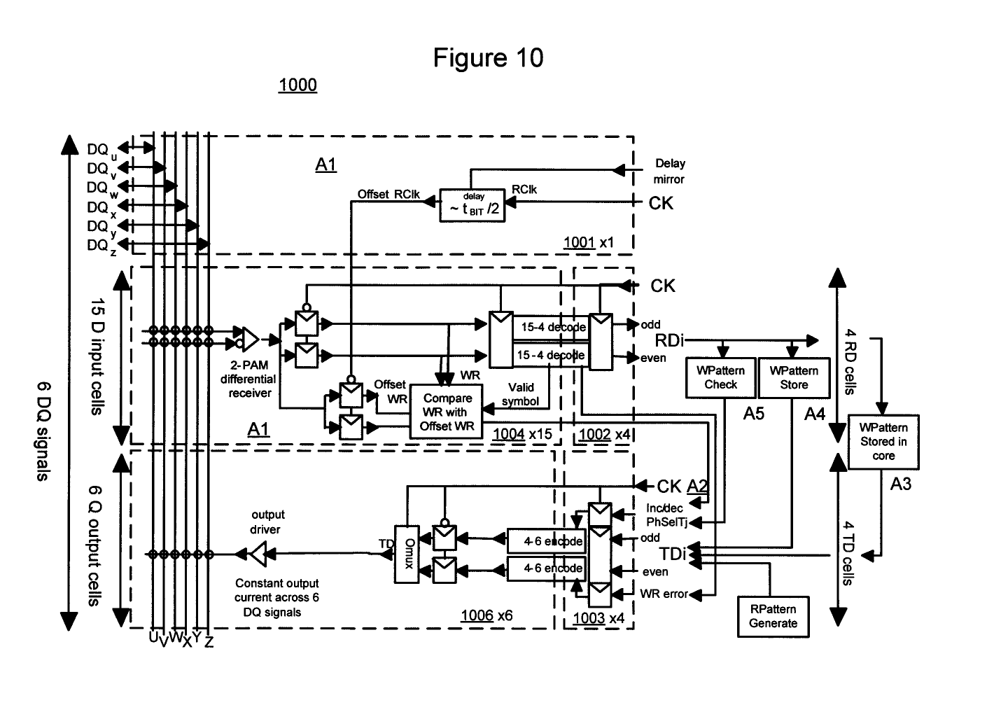

FIG. 9 shows a block diagram illustrating an exemplary memory controller 900 in accordance with an embodiment of the present disclosure. Correspondingly, FIG. 10 shows a block diagram illustrating an exemplary clock-based memory device 1000 in accordance with an embodiment of the present disclosure. The memory controller 900, when in a clock mode, may interoperate with the memory device 1000.

Referring to FIG. 9, there is shown one 6/4 slice of the memory controller 900 which involves 4 bits of DQ data encoded on 6 data wires U-Z (corresponding to 6 signals DQ_{U}-DQ_{Z}) according to a multi-wire encoding scheme as described above in connection with FIGS. 3 and 4. The complete memory controller 900 may include 8 identical 6/4 slices in order to cover 32 bits of DQ data. The 6/4 slice shown may comprise a phase mixing circuit 901, 4 RD cells 902, 4 TD cells 903, 15 Q input cells 904, and 6 D output cells 905.

The phase mixing circuit 901 may include a first phase-mixing portion for a receive clock (RClk) and a second phase-mixing portion for a transmit clock (TClk), each of which may comprise a phase select register (PhSelRi and PhSelTi, respectively) and a phase-mixing unit. RClk/TClk may be generated based on PCLK, PCLK phase offsets, and read/write offset supplied by the phase select registers.

Each Q input cell 904 may comprise a 2-PAM differential receiver to sense the difference between a respective two data wires. The Q input cells 904 may receive multi-wire encoded data under timing control of clock signals RClk and Offset RClk (i.e., RClk with a phase offset or delay) and then compare resulting received RD and Offset RD data streams for read phase maintenance. The multi-wire encoded data may be decoded to retrieve the 4-bit DQ data for output via the 4 RD cells 902. Additional symbols may be retrieved and used for phase calibration purposes, for example, as indicated by the signal labeled “Inc/dec PhSelRj” in the phase mixing circuit 901.

The TD cells 903 may receive 4-bit DQ input data and encode the data (according to the multi-wire encoding scheme) onto the data wires U-Z via the D output cells 905. The output drivers in the D output cells 905 may cause a constant total current to be maintained across the data wires U-Z.

The blocks labeled “delay ˜t_{BIT}/2” and the signal “Offset TD” in the output cell 905 may be used for write phase maintenance employing the methods illustrated in FIG. 6 or FIG. 7. The signals “RD error” and “WR error” in the RD cell 902 may indicate that one or more errors have been detected in read data and write data, respectively. In the TD cell 903, a data mask (DM) input may indicate whether the four bits of data TDi is to be written or not. The DM input may be encoded as a 17^{th} symbol Q when it indicates no-write.

Referring to FIG. 10, there is shown one 6/4 slice of the memory device 1000, which is to some extent a mirror image of the 6/4 slice of the memory controller 900 shown in FIG. 9. To properly exchange data with the memory controller 900 based on the above-described multi-wire encoding scheme, the 6/4 slice of the memory device 1000 may comprise 15 D input cells 1004, which receive data from the 6 D output cells 905, and 6 Q output cells 1006, which transmit data to the 15 Q input cells 904. There may be 4 RD cells 1002 and 4 TD cells 1003 that are similar to the RD cells 902 and TD cells 903 as shown in FIG. 9. There may also be a “WPattern store” unit for storing data patterns (“write patterns”) used for write phase maintenance. Alternatively, or in addition, the write patterns may be stored in a memory core of the memory device 1000.

The memory device 1000 may further comprise a “RPattern generate” unit for generating data patterns (“read patterns”) used for read phase maintenance. During a memory core refresh, the read patterns may be transmitted to the memory controller 900 via the TD cells 1003 and the Q output cells 1006. A “delay ˜t_{BIT}/2” block in cell 1001 may generate an Offset RClk signal which may be used for write phase adjustment (in a similar manner as illustrated in FIG. 6). Alternatively, the write phase adjustment method as illustrated in FIG. 7 may be implemented, for example, based on a comparison block labeled “Compare WR with Offset WR” in the D input cells 1004.

According to embodiments of the present disclosure, phase mixing circuitry in each DQ slice may be shared to either adjust receive clock phase or to delay a read strobe (RDQS). Similarly, the phase mixing circuitry in each DQ slice may be shared to either adjust transmit clock phase or to delay a write strobe (WDQS), wherein a delay requirement (t_{DQSS}) between a write command and a corresponding first DQS rising edge may be more easily satisfied. The phase mixing circuitry in each DQ slice may allow trace variability in a strobe mode. A preamp stage of input receiver(s) may be designed to accept differential input or single-ended input with reference as a board or package option. According to further embodiments, strobe signals may be used in a clock mode as sideband signals for continuous calibration purposes. A memory controller in a clock mode may conserve quad data rate (QDR) pins on a DQ slice by borrowing the phase mixer in the adjacent (unused) DQ slice and setting it to 90°/270°. The reference voltage for a single-ended mode may be routed from the interior of a package such that it does not add to an escape limit of a metal system of the package.

Despite the advantages of the clocked timing architecture, it may be difficult for it to displace the standard, strobed timing architecture because these two types of memory architectures require very different memory controllers. Unless some degree of backward compatibility is provided, customers would be reluctant to upgrade from standard, strobe-timed memory devices used in the standard, strobed timing architecture to currently non-standard, clock-based memory devices used in the clocked timing architecture. The backward compatibility would require that a memory controller be able to work with both strobe-timed memory devices and clock-based memory devices. It would be desirable (though not required) that the circuit boards supporting the two different memory architectures be identical.

Accordingly, it may be desirable to implement a bimodal memory controller that is capable of operating with both strobe-timed memory devices and clock-based memory devices, via, preferably, a common set of conductors on a printed circuit board. With a strobe-timed memory device (or in a “strobe mode”), the memory controller may receive data from and transmit data to the memory device under timing control of read and write strobes, respectively. Accordingly, in the strobe mode, the set of conductors may be grouped to include a first plurality of data conductors and a first plurality of signaling conductors. With a clock-based memory device (or in a “clock mode”), the memory controller may receive data from and transmit data to the memory device under timing control of internally generated transmit and receive clock signals. Accordingly, in the clock mode, the set of conductors may be re-grouped to include a second plurality of data conductors, which include the first plurality of data conductors and at least some of the first plurality of signaling conductors.

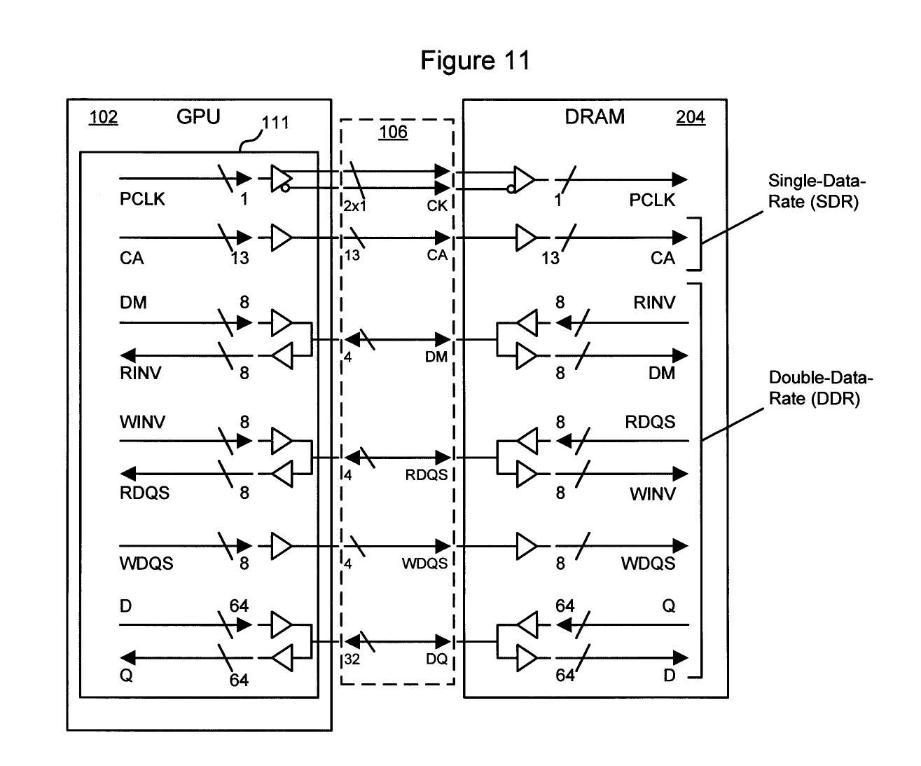

Referring to FIG. 11, there is shown an exemplary bimodal memory controller 102 operating in a strobe mode with a strobe-timed DRAM device 204 in accordance with an embodiment of the present disclosure. The strobe-timed DRAM device 204 may be a GDDR memory device (e.g., GDDR3 or GDDR4). The GPU 102 may be coupled to the DRAM 204 via the same communications link 106. The communications link 106 may still comprise the same conductors or wires as shown in FIG. 2. However, in the strobe mode, the memory interface 111 may cause the conductors or wires in the communications link 106 to be substantially re-grouped to serve differently designated functions. For example, the communications link 106 may now comprise 32 data wires (DQ) and signaling paths for differential clock (CK), control address (CA), data mask (DM), and read/write strobe (RDQS/WDQS) signals. The data wires DQ may form a 32-bit high-speed bi-directional data bus to carry double-data-rate (DDR) transmissions of 64-bit data in one bit time (t_{BIT}) that are read from or written to the DRAM 204 (i.e., D and Q). The WDQS strobe path may be a 4-bit uni-directional signaling path that carries WDQS strobe signals from the GPU 102 to the DRAM 204. The RDQS and DM paths may be 4-bit bi-directional DDR signaling paths, which may additionally carry other signals such as “write invalid” (WINV) and “read invalid” (RINV). The CA path may be a 13-bit, uni-directional single-data-rate (SDR) signaling path.

To switch from the strobe-mode embodiment shown in FIG. 11 to the clock-mode embodiment shown in FIG. 2, those wires that form the RDQS, WDQS and DM signaling paths (as shown in FIG. 11) may be re-grouped with the original 32 data wires (DQ). In addition, another 4 CA wires (out of the 13 CA wires shown in FIG. 11) may be re-allocated for DQ coding. As a result, there may be a total of 48 data wires (DQ) in the clock-mode embodiment shown in FIG. 2. In some embodiments, where there are 16 wires carrying strobe and mask information in addition to the 32 data wires, it may not be necessary to borrow any of the CA wires when switching from the strobe mode to the clock mode.

At this point it should be noted that the techniques for improved timing control of memory devices in accordance with the present disclosure as described above typically involves the processing of input data and the generation of output data to some extent. This input data processing and output data generation may be implemented in hardware or software. For example, specific electronic components may be employed in a semiconductor memory or similar or related circuitry for implementing the functions associated with improved timing control of memory devices in accordance with the present disclosure as described above. Alternatively, one or more processors operating in accordance with stored instructions may implement the functions associated with improved timing control of memory devices in accordance with the present disclosure as described above. If such is the case, it is within the scope of the present disclosure that such instructions may be stored on one or more processor readable carriers (e.g., a magnetic disk), or transmitted to one or more processors via one or more signals.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. For example, some of the embodiments in this disclosure have been described using the multi-wire encoding scheme in FIGS. 3 and 4 as an example, but other multi-wire encoding scheme such as the ones known in the art can also be used with appropriate modifications of the embodiments described herein by those skilled in the art. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1. A memory controller to communicate with a memory device via a communications link having a plurality of conductors, the memory controller comprising:
a memory interface to exchange data with the memory device via a set of N conductors according to at least one clock, the data being encoded such that each M bits of data are represented by at least one symbol and each symbol is associated with a combination of signal levels on a subset of the N conductors, wherein M<N and the subset includes at least one and as many as all of the N conductors; and
clock control logic to receive timing calibration information from the memory device and to output a signal to adjust a phase of the at least one clock based on the timing calibration information.

2. The memory controller of claim 1, wherein the memory controller receives the timing calibration information from the memory device together with read data via the set of N conductors.

3. The memory controller according to claim 1, wherein the subset of conductors is one of a plurality of subsets of n conductors included within the set of N conductors, and wherein a total output current on each subset of n conductors is maintained at a substantially constant level over a period of time during which different symbols are transmitted over the n conductors.

4. The memory controller according to claim 1, wherein the control logic is configured to recognize one or more calibration symbols in an incoming symbol stream during a read operation and output the signal to adjust the at least one clock based on each recognized calibration symbols.

5. The memory controller according to claim 4, wherein the one or more calibration symbols also represent a specific set of data represented by a different symbol.

6. The memory controller according to claim 1, wherein the memory interface is configured to transmit a data mask symbol in place of a symbol representing a set of data to be masked.

7. The memory controller according to claim 1, wherein the timing calibration information is exchanged during a core refresh of the memory device.

8. The memory controller according to claim 1, wherein the memory controller is configurable to operate in a strobe-based mode in which the memory controller regroup the set of N conductors to communicate with a strobe-based memory device.

9. The memory controller according to claim 1, wherein the at least one clock comprises a transmit clock, and wherein the timing calibration information comprises instruction to change a phase of the transmit clock.

10. The memory controller according to claim 1, wherein the at least one clock comprises a receive clock, and wherein the timing calibration information comprises instruction to change a phase of the receive clock.

11. The memory controller according to claim 1, wherein the clock control logic further comprises phase mixing circuitry that controls calibration of the phase of the at least one clock.

12. The memory controller according to claim 1, wherein the controller is configured to calibrate a read phase offset on a continuous basis, and to calibrate a write phase offset on a periodic basis.

13. A method for communicating with a memory device via a communications link having a plurality of conductors, the method comprising the steps of:
exchanging data with the memory device via a set of N conductors according to at least one clock, the data being encoded such that each M bits of data are represented by at least one symbol and each symbol is associated with a combination of signal levels on a subset of the N conductors, wherein M<N and the subset includes at least one and as many as all of the N conductors;
receiving timing calibration information from the memory device; and
outputting a signal to adjust a phase of the at least one clock based on the timing calibration information.

14. The method of claim 13, further comprising:
receiving the timing calibration information from the memory device together with read data via the set of N conductors.

15. The method of claim 13, wherein the subset of conductors is one of a plurality of subsets of n conductors included within the set of N conductors, and wherein a total output current on each subset of n conductors is maintained at a substantially constant level.

16. The method of claim 13, further comprising:
transmitting the timing calibration information with one or more extra symbol that are not used to transmit the data on the set of N conductors.

17. The method of claim 13, further comprising:
transmitting a write-mask-enable signal with an extra symbol that is not used to transmit the data on the set of N conductors.

18. The method of claim 13, wherein the timing calibration information is exchanged during a core refresh of the memory device.

19. The method of claim 13, further comprising:
re-grouping the set of N conductors to communicate with the memory device in response to the memory device being one that operates based on a strobed timing architecture.

20. At least one signal embodied in at least one carrier wave for transmitting a computer program of instructions configured to be readable by at least one processor for instructing the at least one processor to execute a computer process for performing the method as recited in claim 13.

21. At least one processor readable carrier for storing a computer program of instructions configured to be readable by at least one processor for instructing the at least one processor to execute a computer process for performing the method as recited in claim 13.

22. A system for improved timing control of memory devices, the system comprising:
a memory device;
a memory controller;
a communications link coupling the memory controller to the memory device, the communications link comprising a plurality of conductors;
wherein the memory controller exchanges data with the memory device via a set of N conductors according to at least one clock, the data being encoded such that each M bits of data form at least one symbol represented by a combination of signal levels on a subset of the set of N conductors, wherein M<N and the subset includes at least one and as many as all of the N conductors; and
wherein the memory controller receive timing calibration information from the memory device and to adjust a phase of the at least one clock based on the timing calibration information.

23. A method for bimodal control of memory devices, the method comprising the steps of:
coupling with a memory device via a communications link comprising a plurality of conductors;
in response to the memory device being one that operates based on a strobed timing architecture, exchanging data with the memory device via a first set of data conductors among the plurality of conductors; and
in response to the memory device being one that operates based on a clocked timing architecture, exchanging data with the memory device via a second set of data conductors among the plurality of conductors, the second set of data conductors including at least one data conductor from the first set of data conductors and at least one conductor not from the first set of data conductors.

24. The method according to claim 23, wherein the second set of data conductors has a higher number of data conductors than the first set of data conductors, and wherein data exchanged via the second set of data conductors are encoded into symbols using a multi-wire encoding scheme.

25. A method for bimodal control of memory devices, the method comprising the steps of:
coupling a memory controller with a first memory device via a communications link comprising a plurality of conductors, wherein the first memory device operates based on a first timing architecture;
grouping the plurality of conductors into a first plurality of data conductors and a first plurality of signaling conductors;
causing the memory controller to communicate with the first memory device in a first mode;
coupling the memory controller with a second memory device via the communications link, wherein the second memory device operates based on a second timing architecture;
re-grouping the plurality of conductors into a second plurality of data conductors and a second plurality of signaling conductors; and
causing the memory controller to communicate with the second memory device in a second mode.

26. A memory controller comprising:
a memory interface to couple with a memory device via a communications link including a plurality of conductors;
wherein the memory interface transmits and receives data signals via a first set of the plurality of conductors and transmits and receives strobe signals via a second set of the plurality of conductors when the memory controller operates in a strobe mode; and
wherein the memory interface transmits and receives data signals via a third set of the plurality of conductors when the memory controller operates in a clock mode, the third set of the plurality of conductors including the first set of the plurality of conductors and at least some of the second set of the plurality of conductors.

27. The memory controller according to claim 26, wherein the memory interface also transmits and receives timing calibration information via at least some of the third set of the plurality of conductors when the controller operates in the clock mode.

28. The memory controller according to claim 27, wherein the third set of the plurality of conductors includes a plurality of subsets of n conductors and the memory interface is configured to transmit or receive m bits of information at a time via each subset of the n conductors when the controller operates in the clock mode, wherein m<n.

29. The memory controller according to claim 28, further configured to transmit a test sequence to the memory device during a core refresh of the memory device when the controller operates in the clock mode.

30. A memory controller to communicate with a memory device via a communications link having a plurality of conductors, the memory controller comprising:
a memory interface to exchange data with the memory device via a set of N conductors according to at least one clock, the data being encoded such that each M bits of data are represented by least one symbol and each symbol is associated with a combination of signal levels on a subset of the N conductors, wherein M<N and the subset includes at least one and as many as all of the N conductors; and
a control circuit to cause a symbol representing data to be masked be replaced with a data mask symbol.

31. A memory device, comprising:
a receive circuit to receive signals representing write data conveyed via a set of data wires;
a logic circuit to derive phase calibration information based on outputs from the receive circuit; and
a transmit circuit to transmit a signal representing the phase calibration information over the set of data wires.

32. The memory device of claim 31, wherein the signal representing the phase calibration information also represents a specific set of read data.

33. A memory system, comprising:
a memory controller to transmit signals over a set of data wires, the signals including data symbols and one or more data mask symbols, a respective data symbol representing a respective set of write data, and a data mask symbol being sent in place of data being masked; and
a memory device to receive the signals from the set of wires, the memory device being configured to recognize each data mask symbol in the signals as a data mask.
